(19) United States
(12) Patent Application Publication
(10) Pub. No.: US 2026/0303099 A1
(43) Pub. Date: Oct. 1, 2026

(54) MEMRISTOR-BASED MAJORITY CIRCUIT, CONTROL METHOD, DEVICE, AND APPLICATION

(71) Applicant: HUAZHONG UNIVERSITY OF SCIENCE AND TECHNOLOGY, Hubei (CN)

(72) Inventors: Xingsheng Wang, Hubei (CN); Zhouchao Gan, Hubei (CN); Mengjie Li, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/394,782

(22) Filed: Nov. 19, 2025

(30) Foreign Application Priority Data
Mar. 26, 2025 (CN) 202510361198.4

(51) Int. Cl. H03K 19/23; H03K 19/21

(52) U.S. Cl. CPC H03K 19/23; H03K 19/21

(57) ABSTRACT

Provided are a memristor-based majority circuit, control method, device, and application, including a resistor and two identical memristors M₁, M₂ whose negative electrodes are both connected to a terminal of the resistor. The resistance state characteristics of memristors are fully utilized. By setting a resistance state of the memristor M₁ to correspond to a logic value c on the basis that an initial resistance state of the memristor M₂ is a high resistance value state, input voltages of the positive electrodes of the memristors M₁, M₂, and another terminal of the resistor correspond one-to-one to a voltage −V(b)−Vₚ related to a logic value b, a voltage V(a) related to a logic value a, and a voltage −V(b) related to a logic value b, thereby implementing a majority operation of logic values a, b, c. Two memristors only are used to implement the majority operation, reducing circuit area overhead.

### CROSS-REFERENCE TO RELATED APPLICATION

This application claims the priority benefit of China application serial no. 202510361198.4, filed on Mar. 26, 2025. The entirety of the above-mentioned patent application is hereby incorporated by reference herein and made a part of this specification.

### BACKGROUND

### Technical Field

The disclosure belongs to a technical field of a microelectronic device, and in particular to a memristor-based majority circuit, control method, device, and application.

### Related Art

XOR-Majority Graph (XMG) is a combinational logic based on three-input majority (MAJ) and XOR. MAJ implements a fault-tolerant decision function by outputting the majority value of input signals (MAJ(a,b,c)=ab+ac+bc), while XOR executes linear operations through a parity check mechanism (XOR(a,b)=a⊕b). Both constitute a complete logic basis and may iteratively implement arbitrary Boolean functions. XMG deeply integrates two types of logic through topological optimization, demonstrating significant advantages in arithmetic operations, fault-tolerant computing, and cryptography fields. Particularly, in the design of an adder, XMG may implement a carry generation core logic by MAJ, cooperating with XOR to complete a sum bit calculation. This characteristic makes XMG an ideal choice for constructing high-efficiency arithmetic units such as full adders and multipliers. The key point and difficulty in implementing XMG lies in implementing MAJ. Therefore, studying the MAJ circuit has important significance.

Currently, existing MAJ circuits are mostly implemented based on the traditional CMOS technology, but this type of technology has obvious problems. First, traditional CMOS circuits require multiple different logic gates and levels to implement XMG, resulting in complex circuit design and large power consumption and area. Second, in order to separately implement XOR and MAJ, independent circuit units usually need to be designed, which may generate redundancy and reduce resource utilization. Therefore, how to reduce circuit complexity, eliminate redundancy and improve performance has become the main challenge in current technology.

Memristors, with non-volatile resistance state storage and threshold regulation characteristics thereof, provide a disruptive solution for efficient implementation of MAJ, but existing memristor-based MAJ circuits are composed of three memristors and one fixed-value resistor, with a large number of memristors, resulting in significant circuit area overhead.

### SUMMARY

In view of the aforementioned defects or improvement requirements of the existing technology, the disclosure provides a control method and device of a memristor-based majority circuit and addition circuit, configured to solve the technical problem of large area overhead of existing memristor-based majority circuits.

In order to achieve the aforementioned objective, in the first aspect, the disclosure provides a memristor-based majority circuit, configured to perform a majority operation on logic values a, b, c, including a resistor and two identical memristors M₁, M₂. A negative electrode of the memristor M₁ and a negative electrode of the memristor M₂ are both connected to a terminal of the resistor.

Before the majority circuit performs the majority operation on the logic values a, b, c, a resistance state of the memristor M₂ is a high resistance value state.

When the majority circuit performs the majority operation on the logic values a, b, c, a resistance state of the memristor M₁ is a resistance state corresponding to the logic value c. A positive electrode of the memristor M₁ is configured to connect a voltage −V(b)−Vₚ. A positive electrode of the memristor M₂ is configured to connect a voltage V(a). Another terminal of the resistor is configured to connect a voltage −V(b). A final resistance state of the memristor M₂ is a majority operation result of the logic values a, b, c.

A high resistance state of a memristor corresponds to a logic value “0”. A low resistance state corresponds to a logic value “1”. When b is 1, V(b) is Vp. When b is 0, V(b) is a voltage with an amplitude of 0. When a is 1, V(a) is Vp. When a is 0, V(a) is a voltage with an amplitude of 0. A voltage Vp satisfies: Vset/2<Vp<Vset, and Vp<2|Vreset|/3. Vset is a threshold for the memristor to transform from the high resistance state to the low resistance state. Vreset is a threshold for the memristor to transform from the low resistance state to the high resistance state. A resistance value of the resistor indicates R=\sqrt{R_{H}·R_{L}}, where R_{H} and R_{L} are a high resistance state value and a low resistance state value of the memristor respectively.

In the second aspect, the disclosure provides a control method of the majority circuit, including following steps.

When the majority operation is performed on the logic values a, b, c, the resistance state of the memristor M₁ is set to the resistance state corresponding to the logic value c, the voltage −V(b)−Vₚ is connected to the positive electrode of the memristor M₁, the voltage V(a) is connected to the positive electrode of the memristor M₂, the voltage −V(b) is connected to a terminal of the resistor not connected to the memristors, and the final resistance state of the memristor M₂ is used as the majority operation result of the logic values a, b, c.

Before the majority operation is performed on the logic values a, b, c, the resistance state of the memristor M₂ is the high resistance value state.

In the third aspect, the disclosure provides a majority operation device, including a controller and the majority circuit provided in the first aspect of the disclosure.

The controller is configured to execute the control method of the majority circuit provided in the second aspect of the disclosure.

In the fourth aspect, the disclosure provides a control method of an addition circuit. The addition circuit includes a resistor and four identical memristors M1, M2, M3, M4. Negative electrodes of the four memristors are all connected to the terminal of the resistor. The resistance value of the resistor indicates R=\sqrt{R_{H}·R_{L}}, where R_{H} and R_{L} are the high resistance state value and the low resistance state value of the memristor respectively.

The control method includes performing an addition operation on the addition circuit to implement a 1-bit addition of addends a, b and a carry input c.

S1: the memristor M₁ is set to the resistance state corresponding to c. At this time, the resistance states of the memristors M₂, M₃, M₄ are the high resistance value states.

S2: the positive electrode of the memristor M₃ and the positive electrode of the memristor M₄ are made to be in the floating states, the voltage −V(b)−Vₚ is connected to the positive electrode of the memristor M₁, the voltage V(a) is connected to the positive electrode of the memristor M₂, the voltage −V(b) is connected to the terminal of the resistor not connected to the memristors, and thereby the majority operation result of a, b, c corresponding to the resistance state of the memristor M₂ is obtained and act as a carry result of the addition operation.

The positive electrode of the memristor M₂ and the positive electrode of the memristor M₄ are made to be in floating states. A voltage V(a)−2Vₚ is connected to the positive electrode of the memristor M₁. A voltage with an amplitude of 0 is connected to the positive electrode of the memristor M₃. A voltage −V(a)−Vₚ is connected to the terminal of the resistor not connected to the memristors. Thereby, an XOR operation result of a, c corresponding to the resistance state of the memristor M₃ is obtained.

After the XOR operation result of a, c is obtained, the positive electrode of the memristor M₁ and the positive electrode of the memristor M₂ are made to be in the floating states, a voltage V(b)−2Vₚ is connected to the positive electrode of the memristor M₃, a voltage with an amplitude of 0 is connected to the positive electrode of the memristor M₄, a voltage −V(b)−Vₚ is connected to the terminal of the resistor not connected to the memristors, and thereby the XOR operation result of a, b, c corresponding to the resistance state of the memristor M₄ is obtained and act as the sum result of the addition operation.

The high resistance state of the memristor corresponds to the logic value “0”. The low resistance state corresponds to the logic value “1”. When b is 1, V(b) is Vₚ. When b is 0, V(b) is a voltage with an amplitude of 0. When a is 1, V(a) is Vₚ. When a is 0, V(a) is a voltage with an amplitude of 0. The voltage Vₚ satisfies: Vₛₑₜ/2<Vₚ<Vset, and Vₚ<2|Vᵣₑₛₑₜ|/3. Vₛₑₜ is a threshold for the memristor to transform from the high resistance state to the low resistance state. Vᵣₑₛₑₜ is a threshold for the memristor to transform from the low resistance state to the high resistance state.

In the fifth aspect, the disclosure provides a control method of an addition circuit, configured to implement an addition operation of n-bit numbers an, . . . , a2a1, bn, . . . , b2b1 and a 1-bit carry input c1, where n≥2. The addition circuit includes a resistor and four identical memristors M1, M2, M3, M4. The negative electrodes of the four memristors are all connected to a terminal of the resistor. The resistance value of the resistor indicates R=\sqrt{R_{H}·R_{L}}, where R_{H} and R_{L} are the high resistance state value and the low resistance state value of the memristor respectively.

The control method includes sequentially executing n rounds of an addition subprocesses. In the i-th round of the addition subprocess, aᵢ acts as a, bᵢ acts as b, cᵢ acts as c, and the control method provided in the fourth aspect is executed on the addition circuit, to obtain a carry result cᵢ₊₁ and a sum result sᵢ of the i-th round of the addition operation, where i=1, 2, . . . , n.

In tge sixth aspect, the disclosure provides an addition operation device, including an addition circuit and a controller.

The addition circuit includes a resistor and four identical memristors M1, M2, M3, M4. The negative electrodes of the four memristors are all connected to the terminal of the resistor. The resistance value of the resistor indicates R=\sqrt{R_{H}·R_{L}}, where R_{H} and R_{L} are the high resistance state value and the low resistance state value of the memristor respectively.

The controller is configured to execute the control method of the fourth aspect or the fifth aspect.

In the seventh aspect, the disclosure provides a control method of an addition circuit, configured to implement an addition operation of n-bit numbers an, . . . , a2a1, bn, . . . , b2b1 and a 1-bit carry input c1, where n≥2. The addition circuit includes a resistor and 2n+2 identical memristors. The negative electrodes of the 2n+2 memristors are all connected to the terminal of the resistor. The resistance value of the resistor indicates R=\sqrt{R_{H}·R_{L}}, where R_{H} and R_{L} are the high resistance state value and the low resistance state value of the memristor respectively.

The control method includes selecting one memristor from the 2n+2 memristors as the memristor M₃, and sequentially executing n rounds of the addition subprocesses.

In the i-th round of the addition subprocess, i=1, 2, . . . , n.

When i=1, one memristor is selected from the remaining unselected memristors as the memristor M₁ in the current round of the addition subprocess, and is set to the resistance state corresponding to cᵢ; when i≥2, the memristor M₂ from the previous round of the addition subprocess is used as the memristor M₁ in the current round of the addition subprocess.

Two memristors are selected from the remaining unselected memristors as M₂ and M₄ in the current round of the addition subprocess respectively. The sub-addition circuit in the current round is constituted by the memristor M₃ and the memristors M₁, M₂ and M₄ in the current round of the addition subprocess constitute, where the memristor M₃ and the memristors M₂, M₄ in the current round of the addition subprocess are in the high resistance value states.

aᵢ acts as a, bᵢ acts as b, cᵢ acts as c, and S2 is executed in the control method provided by the fourth aspect on the sub-addition circuit in the current round, to obtain a carry result cᵢ₊₁ and a sum result sᵢ of the i-th round of the addition operation.

In each round of the addition subprocess, the positive electrodes of all remaining memristors except the memristor M₃ and the memristors M₁, M₂ and M₄ in the current round of the addition subprocess are in the floating states.

After n rounds of the addition subprocesses, sₙ, . . . , s₂s₁, and cₙ₊₁ are the results of the required addition operation.

In the eighth aspect, the disclosure provides an addition operation device, including an addition circuit and a controller. The addition circuit includes a resistor and 2n+2 identical memristors. Negative electrodes of the 2n+2 memristors are all connected to the terminal of the resistor. The resistance value of the resistor indicates R=\sqrt{R_{H}·R_{L}}, where R_{H} and R_{L} are the high resistance state value and the low resistance state value of the memristor respectively, and n≥2.

The controller is configured to execute the control method provided by the seventh aspect.

In the ninth aspect, the disclosure provides a control method of an addition circuit, configured to implement an addition operation of n-bit numbers an, . . . , a2a1, bn, . . . , b2b1 and a 1-bit carry input c1, where n≥2. The addition circuit includes n parallel branches and switch modules m1, m2, . . . , mn−1 configured to control connection or disconnection between adjacent two branches. The i-th switch module mi is configured to control the connection or disconnection between the i-th branch and the (i+1)-th branch, where i=1, 2, . . . , n−1. The i-th branch includes the i-th resistor Ri and three memristors whose negative electrodes are connected to a terminal of a resistor Ri. The n-th branch includes the n-th resistor Rn and four memristors whose negative electrodes are connected to a terminal of a resistor Rn. All memristors of the addition circuit are identical. All resistors are identical. The resistance value indicates is R=\sqrt{R_{H}·R_{L}}, where R_{H} and R_{L} are the high resistance state value and the low resistance state value of the memristor respectively.

The control method includes following steps.

S1: n−1 rounds of a carry calculation subprocesses are sequentially executed. In the i-th round of the carry calculation subprocess, the i-th switch module mᵢ is controlled to conduct to connect the i-th branch with the (i+1)-th branch, and other switch modules are disconnected.

When i=1, one memristor is selected from the i-th branch as the memristor M₁ in the i-th round of the carry calculation subprocess, and set to the resistance state corresponding to c₁; when i≥2, the memristor M₂ from the previous round of the carry calculation subprocess is used as the memristor M₁ in the current round of the carry calculation subprocess.

One memristor is selected from the (i+1)-th branch as the memristor M₂ in the i-th round of the carry calculation subprocess. At this time, the resistance state of the memristor M₂ is the high resistance value state, and the positive electrodes of all other memristors except the memristors M₁ and M₂ in the current round of the carry calculation subprocess are made to be in the floating states.

The voltage −V(bᵢ)−Vₚ is connected to the positive electrode of memristor M₁ in the current round of the carry calculation subprocess. The voltage V(aᵢ) is connected to the positive electrode of the memristor M₂ in the current round of the carry calculation subprocess. The voltage −V(bᵢ) is connected to a terminal of a resistor Rᵢ or a resistor Rᵢ₊₁ connected to memristors. Thereby, the majority operation result of aᵢ, bᵢ, cᵢ corresponding to the resistance state of memristor M₂ is obtained in the current round of the carry calculation subprocess, and used as a carry result of the i-th round of the addition operation.

S2, all switch modules are disconnected, so that all branches are not connected. The n-th round of the carry calculation subprocess is executed, and n rounds of sum calculation subprocesses in parallel are executed.

Executing the n-th round of the carry calculation subprocess includes following steps.

The memristor M₂ from the previous round of the carry calculation subprocess is used as the memristor M₁ in the current round of the carry calculation subprocess. One unselected memristor from the n-th branch is selected as the memristor M₂ in the n-th round of the carry calculation subprocess. At this time, the resistance state of the memristor M₂ is the high resistance value state. The positive electrodes of all other memristors in the n-th branch except the memristors M₁ and M₂ in the current round of the carry calculation subprocess are made to be in the floating states.

The voltage −V(bₙ)−Vₚ is connected to the positive electrode of the memristor M₁ in the current round of the carry calculation subprocess. The voltage V(aₙ) is connected to the positive electrode of the memristor M₂ in the current round of the carry calculation subprocess. The voltage −V(bₙ) is connected to a terminal of the resistor Rₙ connected to the memristors. Thereby, a majority operation result of aₙ, bₙ, cₙ corresponding to the resistance state of the memristor M₂ is obtained in the current round of the carry calculation subprocess, and used as a carry result of the n-th round of the addition operation.

Executing n rounds of the sum calculation subprocesses in parallel includes following steps.

For the j-th branch, the memristor selected as the memristor M₁ in the j-th round of the carry calculation subprocess is used as the memristor Mⱼ₁, and two unselected memristors from the j-th branch are selected as the memristors Mⱼ₃ and Mⱼ₄, where j=1, 2, . . . , n.

A positive electrode of each memristor Mⱼ₄ is made to be in the floating state. A corresponding voltage V(aⱼ)−2Vₚ is connected to a positive electrode of each memristor Mⱼᵢ in parallel. A voltage with an amplitude of 0 is connected to a positive electrode of each memristor Mⱼ₃ in parallel. A corresponding voltage −V(aⱼ)−Vₚ is connected to a terminal of each resistor Rⱼ not connected to the memristors in parallel. Thereby, an XOR operation result of aⱼ and cⱼ corresponding to a resistance state of each memristor Mⱼ₃ in parallel is obtained.

The positive electrode of each memristor Mⱼᵢ is made to be in the floating state. After the XOR operation result of aⱼ and cⱼ is obtained, a corresponding voltage V(bⱼ)−2Vₚ is connected to the positive electrode of each memristor Mⱼ₃ in parallel, a voltage with an amplitude of 0 is connected to the positive electrode of each memristor Mⱼ₄ in parallel, a corresponding voltage −V(bⱼ)−Vₚ is connected to a terminal of each resistor Rⱼ not connected to the memristors in parallel, and thereby the XOR operation result of aⱼ, bⱼ, and cⱼ corresponding to a resistance state of each memristor Mⱼ₄ in parallel is obtained, and used as the sum result of the addition operation.

The high resistance state of the memristor corresponds to the logic value “0”. The low resistance state corresponds to the logic value “1”. When bⱼ is 1, V(bⱼ) is Vₚ. When bⱼ is 0, V(bⱼ) is a voltage with an amplitude of 0. When aⱼ is 1, V(aⱼ) is Vₚ. When aⱼ is 0, V(aⱼ) is a voltage with an amplitude of 0. A voltage Vₚ satisfies: Vₛₑₜ/2<Vₚ<Vₛₑₜ, and Vₚ<2|Vᵣₑₛₑₜ|/3. Vₛₑₜ is a threshold for the memristor to transform from the high resistance state to the low resistance state. Vᵣₑₛₑₜ is a threshold for the memristor to transform from the low resistance state to the high resistance state.

In the tenth aspect, the disclosure provides an addition operation device, including an addition circuit and a controller. The addition circuit includes: n parallel branches and switch modules m1, m2, . . . , mn−1 configured to control connection or disconnection between adjacent two branches, where n≥2. The i-th switch module mi is configured to control connection or disconnection between the i-th branch and the (i+1)-th branch, where i=1, 2, . . . , n−1. The i-th branch includes an i-th resistor Ri and three memristors whose negative electrodes are connected to the terminal of the resistor Ri. The n-th branch includes an n-th resistor Rn and four memristors whose negative electrodes are connected to the terminal of the resistor Rn. All memristors of the addition circuit are identical. All resistors are identical. The resistance value indicates is R=\sqrt{R_{H}·R_{L}}, where R_{H} and R_{L} are the high resistance state value and the low resistance state value of the memristor respectively.

The controller is configured to execute the control method provided in the ninth aspect.

In the eleventh aspect, the disclosure provides a control system, including a memory and a processor. The memory stores a computer program. The processor executes the control method provided in the second aspect, the fourth aspect, the fifth aspect, the seventh aspect, or the ninth aspect of the disclosure when executing the computer program.

In the twelfth aspect, the disclosure further provides a computer-readable storage medium. The computer-readable storage medium includes a stored computer program. When being run by the processor, the computer program controls the device where the storage medium is located to execute the control method provided in the second aspect, the fourth aspect, the fifth aspect, the seventh aspect, or the ninth aspect of the disclosure.

In the thirteenth aspect, the disclosure further provides a computer program product, including computer program/instructions. When the computer program/instructions are executed by the processor, the control method provided in the second aspect, the fourth aspect, the fifth aspect, the seventh aspect, or the ninth aspect of the disclosure is implemented.

Overall, through the aforementioned technical solutions conceived by the disclosure, the beneficial effects may be achieved as follows.

1. The disclosure provides a memristor-based majority circuit and corresponding device, including a resistor and two identical memristors M₁, M₂ whose negative electrodes are both connected to the terminal of the resistor. The disclosure fully utilizes the resistance state characteristics of the memristors, by setting the resistance state of the memristor M₁ to correspond to the logic value c on the basis that an initial resistance state of the memristor M₂ is the high resistance value state, the input voltages of the positive electrode of the memristor M₁, the positive electrode of the memristor M₂, and another terminal of the resistor correspond one-to-one to the voltage −V(b)−Vₚ related to the logic value b, the voltage V(a) related to the logic value a, and the voltage −V(b) related to the logic value b, where Vₛₑₜ/2<Vₚ<Vₛₑₜ, and to ensure that the memristor M₁ is not reset, it is necessary to satisfy Vₚ<2|Vᵣₑₛₑₜ|/3. Based on the above design, when at least two of a, b, c are the logic “1”, the voltages on the terminals of the memristor M₂ are greater than or equal to 2Vₚ, and 2Vₚ>Vₛₑₜ, so that the memristor M₂ undergoes a set process, and the stored logic result of the memristor M₂ is “1”. Conversely, when at most one of a, b, c is logic “1”, the voltages on the terminals of the memristor M₂ are less than or equal to Vₚ, and Vₚ<Vₛₑₜ, so that the memristor M₂ maintains the high resistance state unchanged, storing logic result “0”, thereby implementing the majority operation of the logic values a, b, c. The disclosure needs to implement the majority operation by using two memristors only, reducing circuit area overhead.

2. The disclosure provides the memristor-based majority circuit and corresponding device. The characteristics of the memristors enable the circuit to have stronger fault tolerance capability, and may still maintain high stability when some components fail.

3. The fourth aspect of the disclosure provides the control method of the addition circuit. The addition circuit includes a resistor and four identical memristors M₁, M₂, M₃, M₄ whose negative electrodes are connected to the terminal of the resistor. On the basis that the initial resistance states of the memristors M₂, M₃, M₄ are the high resistance value states, the resistance state of the memristor M₁ is set to correspond to the logic value c, the memristors M₁, M₂ are selected to execute the majority operation on the logic values a, b, c, the memristors M₁, M₃ are selected to execute the XOR operation on the logic values a, c, the memristors M₃, M₄ are selected to execute the XOR operation on the XOR operation result of a, c and the logic value b. Throughout the entire process, the circuit elements that implement the majority operation and the process that implements the XOR operation adopt a unified circuit structure, and the internal circuit elements may be partially reused, without needing to separately design independent majority operation circuit units and XOR operation circuit units, avoiding redundancy, reducing circuit complexity, lowering circuit area overhead, and improving circuit compactness and resource utilization efficiency.

4. The fifth aspect of the disclosure provides the control method of the addition circuit, configured to implement the addition operation of n-bit numbers aₙ, . . . , a₂a₁, bₙ, . . . , b₂bᵢ and the 1-bit carry input cᵢ. The entire operation process reuses the same addition circuit, only requiring a resistor and four identical memristors whose negative electrodes are connected to the terminal of the resistor to implement a multi-bit number addition operation, reducing circuit complexity, lowering circuit area overhead, and improving circuit compactness and resource utilization efficiency.

5. The seventh aspect of the disclosure provides the control method of the addition circuit. The adopted addition circuit includes a resistor and 2n+2 identical memristors. In the process of implementing the addition operation of n-bit numbers aₙ, . . . , a₂a₁, bₙ, . . . , b₂b₁ and the 1-bit carry input c₁, the carry results calculated by the addition subprocess are stored in the form of resistance states of corresponding memristors for direct use in the next round of the addition subprocess, without requiring additional read and write operations to reduce the complexity of operations.

6. The ninth aspect of the disclosure provides the control method of the addition circuit. The adopted addition circuit includes n parallel branches and the switch module controlling the connection or disconnection between adjacent branches. The i-th branch includes an i-th resistor Rᵢ and three memristors whose negative electrodes are connected to the terminal of the resistor Rᵢ. The n-th branch includes an n-th resistor Rₙ and four memristors whose negative electrodes are connected to the terminal of the resistor Rₙ. The entire operation process first serially performs the first n−1 rounds of the carry calculation subprocesses, then executes the n-th round of the carry calculation subprocess, and performs n rounds of the sum calculation subprocesses in parallel. This method fully combines both serial and parallel approaches. When n takes a large value, the method may further improve computational efficiency.

### BRIEF DESCRIPTION OF THE DRAWINGS

FIG. 1 is a schematic view of a memristor-based majority circuit according to an embodiment of the disclosure.

FIG. 2 is a schematic view of an addition circuit according to an embodiment of the fifth aspect of the disclosure.

FIG. 3 is a schematic view of an addition circuit according to an embodiment of the seventh aspect of the disclosure.

FIG. 4 is a schematic view of an addition circuit according to an embodiment of the ninth aspect of the disclosure.

### DESCRIPTION OF THE EMBODIMENTS

In order to make the objectives, technical solutions, and advantages of the disclosure clearer, the disclosure will be described in further detail below in combination with the accompanying drawings and embodiments. It should be understood that the specific embodiments described herein are merely used to illustrate the disclosure and are not used to limit the disclosure. In addition, the technical features involved in the various embodiments of the disclosure described below may be combined with each other as long as the technical features do not constitute conflicts with each other.

In order to achieve the above objectives, in the first aspect, the disclosure provides a memristor-based majority circuit configured to perform a majority operation on logic values a, b, c, including a resistor and two identical memristors M₁, M₂. Negative electrodes of the memristor M₁ and the memristor M₂ are both connected to a terminal of the resistor.

Before the majority circuit performs the majority operation on the logic values a, b, c, a resistance state of the memristor M₂ is a high resistance state.

When the majority circuit performs the majority operation on the logic values a, b, c, a resistance state of the memristor M₁ is a resistance state corresponding to the logic value c. A positive electrode of the memristor M₁ is configured to connect a voltage −V(b)−Vₚ. A positive electrode of the memristor M₂ is configured to connect a voltage V(a). Another terminal of the resistor is configured to connect a voltage −V(b). The final resistance state of the memristor M₂ is a majority operation result of the logic values a, b, c.

The high resistance state of the memristor corresponds to a logic value “0”. The low resistance state corresponds to a logic value “1”. When b is 1, V(b) is Vₚ. When b is 0, V(b) is a voltage with an amplitude of 0. When a is 1, V(a) is Vₚ. When a is 0, V(a) is a voltage with an amplitude of 0. The voltage Vₚ satisfies: Vₛₑₜ/2<Vₚ<Vₛₑₜ, and Vₚ<2|Vᵣₑₛₑₜ|/3. Vₛₑₜ is a threshold for the memristor to transform from the high resistance state to the low resistance state. Vᵣₑₛₑₜ is a threshold for the memristor to transform from the low resistance state to the high resistance state. A resistance value of the resistor indicating R=\sqrt{R_{H}·R_{L}} clearly distinguishes the low resistance state and the high resistance state of the memristor and the resistance value of the resistor, where R_{H} and R_{L} are the high resistance state value and the low resistance state value of the memristor respectively.

Preferably, in an optional implementation, switching ratios of the memristors M₁, M₂ are both greater than or equal to 100. The switching ratio of the memristor directly affects a resistance state change window of the memristor in an output column. If the switching ratio is larger, the resistance state change window of the memristor becomes larger in the output column. When the switching ratio is greater than or equal to 100, the memristor in the output column may more accurately implement resistance state changes, thereby further improving the accuracy of computation.

In the second aspect, the disclosure provides a control method of the majority circuit, including following steps.

When the majority operation is performed on the logic values a, b, c, the resistance state of the memristor M₁ is set to the resistance state corresponding to the logic value c. The voltage −V(b)−Vₚ is connected to the positive electrode of the memristor M₁. The voltage V(a) is connected to the positive electrode of the memristor M₂. The voltage −V(b) is connected to the terminal of the resistor not connected to the memristor. The final resistance state of the memristor M₂ is used as the majority operation result of the logic values a, b, c.

Before the majority operation is performed on the logic values a, b, c, the resistance state of the memristor M₂ is a high resistance value state.

Related technical solutions are the same as the majority circuit provided in the first aspect of the disclosure, and are not repeated here.

In the third aspect, the disclosure provides a majority operation device, including a controller and the majority circuit provided in the first aspect of the disclosure.

The controller is configured to execute the control method of the majority circuit provided in the second aspect of the disclosure.

Related technical solutions are the same as the majority circuit provided in the first aspect of the disclosure and the control method provided in the second aspect, and are not repeated here.

To further illustrate the memristor-based majority circuit and control method provided by the disclosure, detailed description is given below in combination with a specific embodiment.

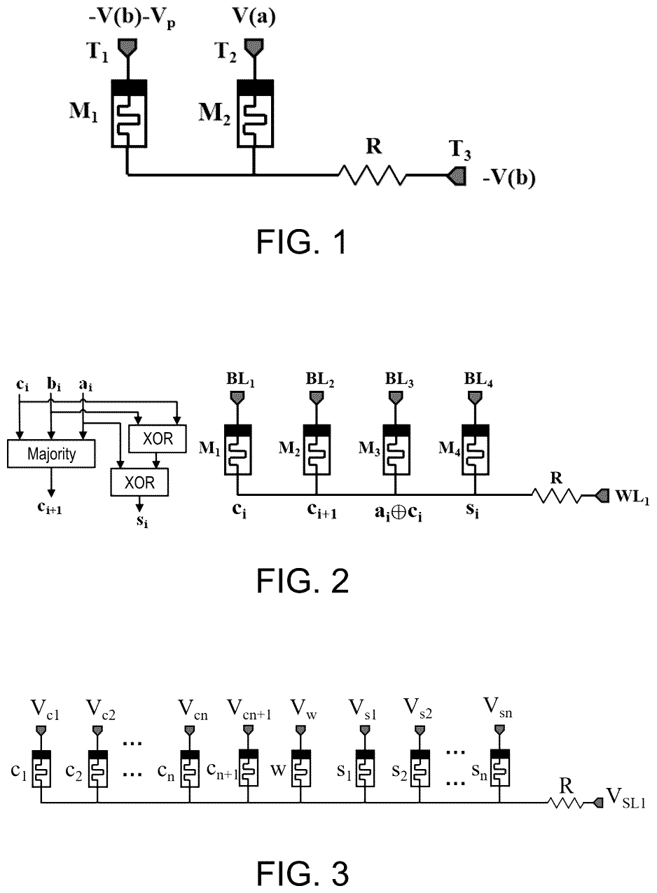

This embodiment provides a memristor-based majority circuit configured to perform the majority operation on the logic values a, b, c. As shown in FIG. 1, the memristor-based majority circuit includes a resistor and two identical memristors M₁, M₂. The negative electrodes of the memristor M₁ and the memristor M₂ are both connected to a terminal of the resistor. The positive electrodes of the memristors M₁, M₂ are controlled by control terminals T₁, T₂. Another terminal (the terminal not connected to the memristors) of the resistor is controlled by a control terminal T₃.

The memristor includes two resistance states, namely a high resistance state (HRS) and a low resistance state (LRS). The memristor may transform between the two resistance states by applying voltages of magnitude in specific directions. By applying a forward voltage greater than Vₛₑₜ, the memristor may be set from the high resistance state to the low resistance state. Conversely, by applying a reverse voltage less than Vᵣₑₛₑₜ, the memristor may transform from the low resistance state to the high resistance state. Vₛₑₜ is the threshold for the memristor to transform from the high resistance state to the low resistance state. Vᵣₑₛₑₜ is the threshold for the memristor to transform from the low resistance state to the high resistance state.

The resistance value of the resistor indicates R=\sqrt{R_{H}·R_{L}}, where R_{H} and R_{L} are the high resistance state value and the low resistance state value of the memristor respectively. Considering that the switching ratio of the memristor directly affects the resistance state change window of the memristor in the output column, the switching ratio is larger, and the resistance state change window of the memristor becomes larger in the output column. When the switching ratio is greater than or equal to 100, the memristor in the output column may more accurately implement resistance state changes, thereby further improving the accuracy of computation. Preferably, the switching ratio of the memristor is greater than or equal to 100. In this embodiment, the high resistance of the memristor indicates R_{H}=100KΩ, and the low resistance thereof indicates R_{L}=1KΩ.

Before the majority circuit performs the majority operation on the logic values a, b, c, the resistance state of the memristor M₂ is the high resistance value state.

When the majority circuit performs the majority operation on the logic values a, b, c:
An input resistance state of the memristor M₁ is determined by the logic value c, having a resistance state corresponding to the logic value c. The high resistance state of the memristor corresponds to the logic value “0”, and the low resistance state corresponds to the logic value “1”;
The input voltage of the control terminal T₁ is determined by the logic value b, which is −V(b)−Vₚ, that is, −V(b)−Vₚ is connected to the positive electrode of the memristor M₁. Specifically, when b is 1, V(b) is Vₚ. When b is 0, V(b) is a voltage with an amplitude of 0;
The input voltage of the control terminal T₂ is determined by the logic value a, which is V(a), that is, the voltage V(a) is connected to the positive electrode of the memristor M₂. Specifically, when a is 1, V(a) is Vₚ. When a is 0, V(a) is voltage with an amplitude of 0;
The input voltage of the control terminal T₃ is determined by logic value b, which is −V(b), that is, voltage −V(b) is connected to the positive electrode of memristor M₂;
The final resistance state of the memristor M₂ is the majority operation result of the logic values a, b, c. When the final resistance state of memristor M₂ is the high resistance state, the corresponding majority operation result is the logic value “0”. When the final resistance state of the memristor M₂ is the low resistance state, the corresponding majority operation result is the logic value “1”.

The voltage Vₚ satisfies: Vₛₑₜ/2<Vₚ<Vₛₑₜ, and to ensure that the memristor M₁ is not reset, it is required to satisfy Vₚ<2|Vᵣₑₛₑₜ|/3, where Vₛₑₜ is the threshold for the memristor to transform from the high resistance state to the low resistance state, and Vᵣₑₛₑₜ is the threshold for the memristor to transform from the low resistance state to the high resistance state. Preferably, in order to provide larger margins for both logic output “1” and logic output “0”, and Vₚ=0.6Vₛₑₜ.

It should be noted that the resistance value of the resistor indicates R=\sqrt{R_{H}·R_{L}}, which acts as voltage division, so that when the memristor M1 is in the low resistance, the voltage on the negative electrode of the memristor M₂ is approximately equal to the voltage on the terminal T1; when the memristor M₁ is in the high resistance, the voltage on the negative electrode of the memristor M₂ is approximately equal to the voltage at terminal T3. Based on the above design, when at least two of the logic values a, b, c are logic “1”, the voltages on the terminals of the memristor M₂ are greater than or equal to 2Vₚ, and 2Vₚ>Vₛₑₜ, so that the memristor M₂ undergoes a set process, and the stored logic result in the memristor M2 is “1”. Conversely, when at most one of the logic values a, b, c is logic “1”, the voltages on the terminals of the memristor M2 are less than or equal to Vₚ, and Vₚ<Vₛₑₜ, so that the memristor M2 maintains the high resistance state, and stores the logic result “0”. Therefore, the majority operation of the logic values a, b, c is implemented.

MAJ and XOR are the core of XMG, and together form a complete logic basis. By combining MAJ and XOR, any Boolean function may be implemented to realize different arithmetic operations. XMG may implement carry generation core logic by MAJ, and cooperate with XOR to complete sum bit calculation. This feature makes XMG an ideal choice for constructing high-efficiency arithmetic units such as adders and multipliers.

Among numerous arithmetic operations, an adder is the most fundamental arithmetic unit in digital circuit design, and the performance thereof directly affects the efficiency and power consumption of data processing. Therefore, the adder is mainly used as an example for introduction here. In the design of existing adder circuits, it is usually necessary to design independent circuit units for MAJ operations and XOR operations respectively, which requires a large number of components and many iterative operation steps, thereby generating a large amount of redundancy and reducing resource utilization.

In order to solve the aforementioned problems, the disclosure provides an application of an implementation method of MAJ provided by the disclosure in the adder operation implementation process, specifically as follows.

In the fourth aspect, the disclosure provides a control method of an addition circuit. The addition circuit includes a resistor and four identical memristors M₁, M₂, M₃, M₄. Negative electrodes of the four memristors are connected to a terminal of the resistor. The resistance value of the resistor indicates R=\sqrt{R_{H}·R_{L}}, where R_{H} and R_{L} are the high resistance state value and the low resistance state value of the memristor respectively.

The control method includes performing an addition operation on the addition circuit to implement 1-bit addends a, b, and a carry input c.

S1: the memristor M₁ is set to the resistance state corresponding to c. At this time, the resistance states of the memristors M₂, M₃, M₄ are the high resistance value states.

S2: positive electrodes of the memristors M₃, M₄ are made to be in floating states, −V(b)−Vₚ is connected to the positive electrode of the memristor M₁, the voltage V(a) is connected to the positive electrode of the memristor M₂, the voltage −V(b) is connected to the terminal of the resistor not connected to the memristor, so that the MAJ operation result of a, b, c corresponding to the resistance state of the memristor M₂ is obtained to act as the carry result of the addition operation.

The positive electrodes of the memristors M₂, M₄ are made to be in the floating states, the voltage V(a)−2Vₚ is connected to the positive electrode of the memristor M₁, a voltage with an amplitude of 0 is connected to the positive electrode of the memristor M3, the voltage −V(a)−Vₚ is connected to the end of the resistor not connected to the memristor, so that the XOR operation result a⊕c of a, c corresponding to the resistance state of the memristor M₃ is obtained.

After the XOR operation result a⊕c is obtained, the positive electrodes of the memristors M₁, M₂ are made to be in the floating states, the voltage V(b)−2Vₚ is connected to the positive electrode of the memristor M₃, a voltage with an amplitude of 0 is connected to the positive electrode of the memristor M₄, the voltage −V(b)−Vₚ is connected to the terminal of the resistor not connected to the memristor, so that the XOR operation result b⊕a⊕c of a, b, c corresponding to the resistance state of the memristor M4 is obtained to act as a sum result of the addition operation.

The high resistance state of the memristor corresponds to the logic value “0”. The low resistance state corresponds to the logic value “1”. When b is 1, V(b) is Vₚ. When b is 0, V(b) is voltage with an amplitude of 0. When a is 1, V(a) is Vₚ. When a is 0, V(a) is voltage with an amplitude of 0. Vₛₑₜ/2<Vₚ<Vₛₑₜ, and Vₚ<2|Vᵣₑₛₑₜ|/3, where Vₛₑₜ is the threshold for the memristor to transform from the high resistance state to the low resistance state, and Vᵣₑₛₑₜ is the threshold for the memristor to transform from the low resistance state to the high resistance state. Preferably, in order to make both logic output “1” and logic output “0” have larger margin, Vₚ=0.6Vₛₑₜ.

It should be noted that the execution order of the MAJ operation of a, b, c, the XOR operation of a, c, and the XOR operation between the XOR result of a, c and logic value b in S2 only needs to ensure that the XOR operation of the logic values a, c is executed before the XOR operation between the XOR result of a, c and the logic value b. The MAJ operation of a, b, c may be executed before the XOR operation of the logic values a, c, or may be executed after the XOR operation of the logic values a, c and before the XOR operation between the XOR result of a, c and the logic value b, or may be executed after the XOR operation between the XOR result of a, c and the logic value b, which is not limited here.

Considering that the switching ratio of the memristor directly affects the resistance state change window of the memristor in the output column, the switching ratio is larger, and the resistance state change window of the memristor becomes larger in the output column. When the switching ratio is greater than or equal to 100, the memristor in the output column may more accurately implement resistance state changes, thereby further improving the accuracy of calculation. Preferably, the switching ratio of the memristor is greater than or equal to 100. In an optional implementation, the high resistance of the memristor indicates R_{H}=100KΩ, and the low resistance thereof indicates R_{L}=1KΩ.

It should be noted that, based on 1 bit addition, the disclosure may further extend to methods of a multi-bit number addition operation. There are multiple methods, and several typical methods are provided as follows.

In the fifth aspect, the disclosure provides a control method of an addition circuit, configured to implement an addition operation of n-bit numbers aₙ, . . . , a₂a₁, bₙ, . . . , b₂b₁, and 1-bit carry input c₁, where n≥2. The addition circuit includes a resistor and four identical memristors M₁, M₂, M₃, M₄. The negative electrodes of the four memristors are all connected to a terminal of the resistor. The resistance value of the resistor indicates R=\sqrt{R_{H}·R_{L}}, where R_{H} and R_{L} are the high resistance state value and the low resistance state value of the memristor respectively.

The control method includes sequentially executing n rounds of an addition subprocesses. As shown in FIG. 2, in the i-th round of the addition subprocess, aᵢ acts as a, bᵢ acts as b, cᵢ acts as c, and the control method provided in the fourth aspect is executed on the addition circuit to obtain a carry result cᵢ₊₁ and a sum result sᵢ of the i-th round addition operation, where i=1, 2, . . . , n.

The specific operations are shown in Table 1.

TABLE 1

| Implementation | BL₁ | BL₂ | BL₃ | BL₄ | WL₁ |
|---|---|---|---|---|---|
| Write Cᵢ | | | | | |
| into M₁ | | | | | |
| M₂ = Cᵢ₊₁ = | −Vₚ (bᵢ = 0); | 0 (aᵢ = 0); | Floating | Floating | 0 (bᵢ = 0); |
| MAJ (aᵢ, bᵢ, cᵢ) | −2Vₚ (bᵢ = 1) | Vₚ (aᵢ = 1) | | | −Vₚ (bᵢ = 1) |
| M₃ = aᵢ ⊕ cᵢ | −2Vₚ (aᵢ = 0); | Floating | 0 | Floating | −Vₚ (aᵢ = 0); |
| | −Vₚ (aᵢ = 1) | | | | −2Vₚ (aᵢ = 1) |
| M₄ = sᵢ = bᵢ ⊕ | Floating | Floating | −2Vₚ (bᵢ = 0); | 0 | −Vₚ (bᵢ = 0); |
| aᵢ ⊕ cᵢ | | | −Vₚ (bᵢ = 1) | | −2Vₚ (bᵢ = 1) |

Through the above implementations, the function of a full adder is implemented, where the 1-bit carry input c₁ is determined by the user and may be logic “1” or logic “0”.

Considering that the switching ratio of the memristor directly affects the resistance state change window of the memristor in the output column, the switching ratio is larger, and the resistance state change window of the memristor becomes larger in the output column. When the switching ratio is greater than or equal to 100, the memristor in the output column may more accurately implement resistance state changes, thereby further improving the accuracy of calculation. Preferably, the switching ratio of the memristor is greater than or equal to 100. In an optional implementation, the high resistance of the memristor indicates R_{H}=100KΩ, and the low resistance of the memristor indicates R_{L}=1KΩ.

Related technical solutions are the same as the control method provided in the fourth aspect of the disclosure, and are not repeated here.

In the sixth aspect, the disclosure provides an addition operation device, including an addition circuit and a controller.

The addition circuit includes: a resistor and four identical memristors M₁, M₂, M₃, M₄. The negative electrodes of the four memristors are all connected to a terminal of the resistor. The resistance value of the resistor indicates R=\sqrt{R_{H}·R_{L}}, where R_{H} and R_{L} are the high resistance state value and the low resistance state value of the memristor respectively.

The controller is configured to execute the control method of the fourth aspect or the fifth aspect described above.

Considering that the switching ratio of the memristor directly affects the resistance state change window of the memristor in the output column, the switching ratio is larger, and the resistance state change window of the memristor becomes larger in the output column. When the switching ratio is greater than or equal to 100, the memristor in the output column may more accurately implement resistance state changes, thereby further improving the accuracy of calculation. Preferably, the switching ratio of the memristor is greater than or equal to 100. In an optional implementation, the high resistance of the memristor indicates R_{H}=100KΩ, and the low resistance of the memristorm indicates R_{L}=1KΩ.

Related technical solutions are the same as the control method provided in the fourth aspect and the fifth aspect of the disclosure, and are not repeated here.

In the seventh aspect, the disclosure provides a control method of an addition circuit, configured to implement an addition operation of n-bit numbers aₙ, . . . , a₂a₁, bₙ, . . . , b₂b₁ and 1-bit carry input c₁, where n≥2. The addition circuit includes a resistor and 2n+2 identical memristors. The negative electrodes of the 2n+2 memristors are all connected to a terminal of the resistor. The resistance value of the resistor R=\sqrt{R_{H}·R_{L}}, where R_{H} and R_{L} are the high resistance state value and the low resistance state value of the memristor respectively.

The control method includes selecting one memristor from the 2n+2 memristors as the memristor M₃, and sequentially executing n rounds of the addition subprocesses.

In the i-th round of the addition subprocess, it is indicated i=1, 2, . . . , n.

When i=1, one memristor is selected from the remaining unselected memristors as the memristor M₁ in the current round of the addition subprocess, and is set to the resistance state corresponding to c₁. When i≥2, the memristor M₂ from the previous round of the addition subprocess is used as the memristor M₁ in the current round of the addition subprocess.

Two memristors are selected from the remaining unselected memristors as M₂, M₄ respectively in the current round of the addition subprocess. The memristor M₃ and the memristors M₁, M₂, M₄ in the current round of the addition subprocess constitute the sub-addition circuit in the current round, where the memristor M₃ and the memristors M₂, M₄ in the current round of the addition subprocess are all in the high resistance value states.

aᵢ acts as a, bᵢ acts as b, cᵢ acts as c, and S2 is executed in the control method provided in the fourth aspect on the sub-addition circuit in the current round, to obtain the carry result cᵢ₊₁ and the sum result sᵢ of the i-th round addition operation.

In each round of the addition subprocess, the positive electrodes of all remaining memristors except the memristor M₃ and the memristors M₁, M₂, M₄ in the current round of the addition subprocess are all in the floating states.

After n rounds of the addition subprocesses, sₙ, . . . , s₂s₁, and cₙ₊₁ are the results of the required addition operation.

FIG. 3 is a schematic view of an addition circuit according to an embodiment of the seventh aspect of the disclosure.

Considering that the switching ratio of the memristor directly affects the resistance state change window of the memristor in the output column, the switching ratio is larger, and the resistance state change window of the memristor becomes larger in the output column. When the switching ratio is greater than or equal to 100, the memristor in the output column may more accurately implement resistance state changes, thereby further improving the calculation accuracy. Preferably, the switching ratio of the memristor is greater than or equal to 100. In an optional implementation, the high resistance of the memristor indicates R_{H}=100KΩ, and the low resistance thereof indicates R_{L}=1KΩ.

Related technical solutions are the same as the control method provided by the fourth aspect of the disclosure, and are not repeated here.

In the eighth aspect, the disclosure provides an addition operation device, including an addition circuit and a controller. The addition circuit includes a resistor and 2n+2 identical memristors. The negative electrodes of the 2n+2 memristors are all connected to a terminal of the resistor. The resistance value of the resistor indicates R=\sqrt{R_{H}·R_{L}}, where R_{H} and R_{L} are the high resistance state value and the low resistance state value of the memristor respectively, and n≥2;

The controller is configured to execute the control method provided by the seventh aspect.

Related technical solutions are the same as the method provided by the seventh aspect of the disclosure, and are not repeated here.

In the ninth aspect, the disclosure provides a control method for an addition circuit, configured to implement an addition operation of n-bit numbers aₙ, . . . , a₂aₙ, bₙ, . . . , b₂b₁, and 1-bit carry input c1, where n≥2. The addition circuit includes n parallel branches, and switch modules m₁, m₂, . . . , mₙ₋₁ configured to control the connection or disconnection between adjacent two branches. The i-th switch module mᵢ is configured to control the connection or disconnection between the i-th branch and the (i+1)-th branch, where i=1, 2, . . . , n−1. The i-th branch includes the i-th resistor Rᵢ and three memristors whose negative electrodes are all connected to a terminal of the resistor Rᵢ. The n-th branch includes the n-th resistor Rₙ and four memristors whose negative electrodes are all connected to a terminal of the resistor Rₙ. All memristors in the addition circuit are identical, all resistors are identical, and the resistance value R indicates R=\sqrt{R_{H}·R_{L}}, where R_{H} and R_{L} are the high resistance state value and the low resistance state value of the memristor respectively.

The control method includes following steps.

S1: n−1 rounds of the carry calculation subprocesses are sequentially executed. In the i-th round of the carry calculation subprocess, the i-th switch module mᵢ is controlled to conduct to connect the i-th branch with the (i+1)-th branch, and all other switch modules are disconnected.

When i=1, one memristor is selected from the i-th branch as the memristor M₁ in the i-th round of the carry calculation subprocess, and is set to the resistance state corresponding to c₁. When i≥2, the memristor M₂ from the previous round of the carry calculation subprocess is used as the memristor M₁ in the current round of the carry calculation subprocess.

One memristor is selected from the (i+1)-th branch as memristor M₂ in the i-th round of the carry calculation subprocess. At this time, the resistance state of the memristor M₂ is the high resistance value state, and the positive electrodes of all other memristors except the memristors M₁ and M₂ in the current round of the carry calculation subprocess are made to be in the floating states.

The voltage −V(bᵢ)−Vₚ is connected to the positive electrode of the memristor M₁ in the current round of the carry calculation subprocess, the voltage V(aᵢ) is connected to the positive electrode of the memristor M₂ in the current round of the carry calculation subprocess, the voltage −V(bᵢ) is connected to the terminal of the resistor Rᵢ or the resistor Rᵢ₊₁ that is not connected to the memristors, so that the MAJ operation result of aᵢ, bᵢ, cᵢ corresponding to the resistance state of the memristor M₂ is obtained in the current round of the carry calculation subprocess, and used as the carry result of the i-th round addition operation.

S2: all switch modules disconnected, so that all branches are not connected. The n-th round of the carry calculation subprocess is executed, and n rounds of the sum calculation subprocesses is executed in parallel.

The above executing the n-th round of the carry calculation subprocess includes following steps.

The memristor M₂ from the previous round of the carry calculation subprocess is used as memristor M₁ in the current round of the carry calculation subprocess, and one unselected memristor is selected from the n-th branch as memristor M₂ in the n-th round of the carry calculation subprocess. At this time, the resistance state of the memristor M₂ is the high resistance value state, so that the positive electrodes of all other memristors in the n-th branch except memristors M₁, M₂ in the current round of the carry calculation subprocess are in the floating states.

The voltage −V(bₙ)−Vₚ is connected to the positive electrode of the memristor M₁ in the current round of the carry calculation subprocess, the voltage V(aₙ) is connected to the positive electrode of the memristor M₂ in the current round of the carry calculation subprocess, and the voltage −V(bₙ) is connected to the terminal of the resistor Rₙ that is not connected to the memristors, so that the MAJ operation result of aₙ, bₙ, cₙ corresponding to the resistance state of the memristor M₂ is obtained in the current round of the carry calculation subprocess, and used as the carry result of the n-th round addition operation.

The above executing n rounds of sum calculation subprocesses in parallel includes the following steps.

For the j-th branch, the memristor that was selected as the memristor M₁ in the j-th round of the carry calculation subprocess is used as a memristor Mⱼ₁, and two unselected memristors from the j-th branch are used as memristors Mⱼ₃ and Mⱼ₄, where j=1, 2, . . . , n.

The positive electrode of each memristor Mⱼ₄ is made to be in the floating state, the corresponding voltage V(aⱼ)−2Vₚ (that is, V(a₁)−2Vₚ, V(a₂)−2Vₚ, . . . , V(aₙ)−2Vₚ connected to the positive electrodes of the memristors M₁₁, M₂₁, . . . , Mₙ₁ in one-to-one correspondence in parallel) is connected to the positive electrode of each memristor Mⱼ₁ in parallel, a voltage with an amplitude of 0 (that is, the voltage with the amplitude of 0 connected to the positive electrodes of M₁₃, M₂₃, . . . , Mₙ₃ in parallel) is connected to the positive electrode of each memristor Mⱼ₃ in parallel, and the corresponding voltage −V(aⱼ)−Vₚ (that is, the voltages −V(a₁)−Vₚ, −V(a₂)−Vₚ, . . . , −V(aₙ)−Vₚ connected to the terminals of the resistors R₁, R₂, . . . , Rₙ that are not connected to memristors in one-to-one correspondence in parallel) is connected to the terminal of each resistor Rⱼ that is not connected to memristors in parallel, so that the XOR operation result (that is, the XOR operation result of a₁ and c₁, the XOR operation result of a₂ and c₂, . . . , and the XOR operation result of aₙ and cₙ corresponding to the resistance states obtained in the memristors M₁₃, M₂₃, . . . , Mₙ₃ in one-to-one correspondence in parallel) of aⱼ and cⱼ corresponding to the resistance state is obtained in each memristor Mⱼ₃ in parallel.

The positive electrode of each memristor Mⱼ₁ is made to be in the floating state. After the XOR operation result of aⱼ and cⱼ is obtained, the corresponding voltage V(bⱼ)−2Vₚ (that is, the voltages V(b₁)−2Vₚ, V(b₂)−2Vₚ, . . . , V(bₙ)−2Vₚ connected to the positive electrodes of the memristors M₁₃, M₂₃, . . . , Mₙ₃ in one-to-one correspondence in parallel) is connected to the positive electrode of each memristor Mⱼ₃ in parallel, a voltage with an amplitude of 0 (that is, the voltage with the amplitude of 0 connected to the positive electrodes of the memristors M₁₄, M₂₄, . . . , Mₙ₄ in parallel) is connected to the positive electrode of each memristor Mⱼ₄ in parallel, and the corresponding voltage −V(bⱼ)−Vₚ (that is, the voltages −V(bᵢ)−Vₚ, −V(b₂)−Vₚ, . . . , −V(bₙ)−Vₚ to the terminals of the resistors R₁, R₂, . . . , Rₙ that are not connected to memristors in one-to-one correspondence connected in parallel) is connected to the terminal of each resistor Rⱼ that is not connected to memristors in parallel, so that the XOR operation result (that is, the XOR operation result of a₁, b₁, and c₁, the XOR operation result of a₂, b₂, and c₂, . . . , the XOR operation result of aₙ, bₙ, and cₙ corresponding to the resistance states obtained in the memristors M₁₄, M₂₄, . . . , Mₙ₄ in one-to-one correspondence in parallel) of aⱼ, bⱼ, and cⱼ corresponding to the resistance state is obtained in each memristor Mⱼ₄ in parallel, and act as the sum result of the addition operation.

The high resistance state of the memristor corresponds to the logic value “0”. The low resistance state corresponds to the logic value “1”. When bⱼ is 1, V(bⱼ) is Vₚ. When bⱼ is 0, V(bⱼ) is a voltage with an amplitude of 0. When aⱼ is 1, V(aⱼ) is Vₚ. When aⱼ is 0, V(aⱼ) is a voltage with an amplitude of 0. The voltage Vₚ satisfies: Vₛₑₜ/2<Vₚ<Vₛₑₜ, and Vₚ<²|Vᵣₑₛₑₜ|/3, where Vₛₑₜ is the threshold for the memristor to transform from the high resistance state to the low resistance state, and Vᵣₑₛₑₜ is the threshold for the memristor to transform from the low resistance state to the high resistance state. Preferably, in order to make both logic output “1” and logic output “0” have larger margins, Vₚ=0.6Vₛₑₜ.

Considering that the switching ratio of the memristor directly affects the resistance state change window of the memristor in the output column, the switching ratio is larger, and the resistance state change window of the memristor becomes larger in the output column. When the switching ratio is greater than or equal to 100, the memristor in the output column may more accurately implement resistance state changes, thereby further improving the accuracy of calculation. Preferably, the switching ratio of the memristor is greater than or equal to 100. In an optional implementation, the high resistance of the memristor indicates R_{H}=100KΩ, and the low resistance thereof indicates R_{L}=1KΩ.

It should be noted that the execution order of executing the nth round of the carry calculation subprocess and executing n rounds of the sum calculation subprocesses in parallel is not limited. Executing the nth round of the carry calculation subprocess may be performed before executing n rounds of the sum calculation subprocesses in parallel, or may be performed after executing n rounds of the sum calculation subprocesses in parallel.

It should be noted that the aforementioned switch module may be any existing switch module, which is not limited here. It may be a switch connected between two adjacent branches, or a switch (one switch module constituted by switches on two adjacent branches) may be disposed on each branch respectively.

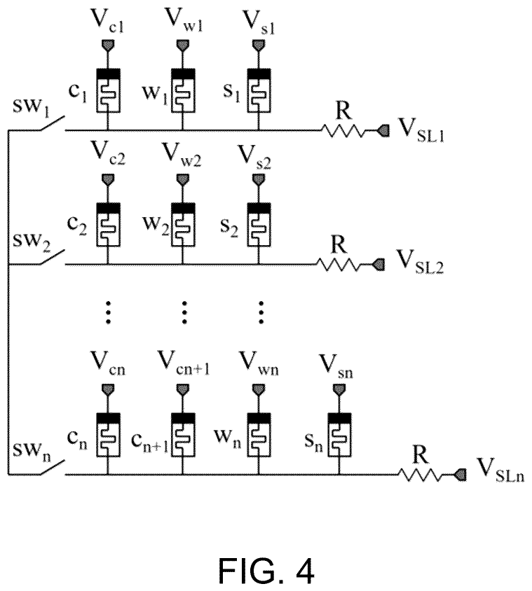

FIG. 4 is a schematic view of an addition circuit according to an embodiment of the ninth aspect of the disclosure. In this schematic view, one switch module includes two switches, respectively set on two adjacent branches.

In the tenth aspect, the disclosure provides an addition operation device, including an addition circuit and a controller. The addition circuit includes n parallel branches and switch modules m₁, m₂, . . . , mₙ₋₁ configured to control connection or disconnection between two adjacent branches, where n≥2. The ith switch module mi is configured to control connection or disconnection between the ith branch and the (i+1)th branch, where i=1, 2, . . . , n−1. The ith branch includes an ith resistor Rᵢ and three memristors whose negative electrodes are all connected to a terminal of the resistor Rᵢ. The nth branch includes an nth resistor Rₙ and four memristors whose negative electrodes are all connected to a terminal of the resistor Rₙ. All memristors in the addition circuit are the same, all resistors are the same, and the resistance value R indicates R=\sqrt{R_{H}·R_{L}}, where R_{H} and R_{L} are the high resistance state value and the low resistance state value of the memristor respectively.

The controller is configured to execute the control method provided by the ninth aspect.

Related technical solutions are the same as the control method provided by the ninth aspect of the disclosure, and are not repeated here.

In summary, the disclosure efficiently implements the MAJ operations and the XOR operations based on the nonlinear and memory characteristics of the memristors, thereby implementing addition operations. The disclosure does not need to separately design independent the MAJ operation circuit units and the XOR operation circuit units, avoiding redundancy. By designing a unified circuit structure, MAJ and XOR may be calculated by the same steps, which reduces circuit complexity, and improves resource utilization. Compared with traditional CMOS circuits, memristor-based circuits may significantly reduce power consumption and area, further improving the overall performance of the circuit.

Based on the above, the solutions of the disclosure have significant advantages. First, the unified circuit structure eliminates redundant design and improves circuit compactness and resource utilization. Second, the memristor circuits may efficiently complete the MAJ operations and the XOR operations under conditions of low power consumption and small area, which is particularly suitable for large-scale parallel computing tasks. Finally, the characteristics of the memristors enable the circuit to have stronger fault tolerance capability and maintain high stability even when some components fail. Therefore, the disclosure solves the redundancy and efficiency problems in the existing technology, and also has high application prospects, especially in the fields of integrated circuits and efficient computing.

In the eleventh aspect, the disclosure provides a control system, including a memory and a processor. The memory stores a computer program. The processor executes the control method provided by the second aspect, the fourth aspect, the fifth aspect, the seventh aspect, or the ninth aspect of the disclosure when executing the computer program.

Related technical solutions are the same as the control methods provided by the second aspect, the fourth aspect, the fifth aspect, the seventh aspect, and the ninth aspect of the disclosure, and are not repeated here.

In the twelfth aspect, the disclosure further provides a computer-readable storage medium. The computer-readable storage medium includes a stored computer program. When run by a processor, the computer program controls the device where the storage medium is located to execute the control method provided by the second aspect, the fourth aspect, the fifth aspect, the seventh aspect, or the ninth aspect of the disclosure.

Related technical solutions are the same as the control methods provided by the second aspect, the fourth aspect, the fifth aspect, the seventh aspect, and the ninth aspect of the disclosure, and are not repeated here.

In the thirteenth aspect, the disclosure further provides a computer program product, including computer program/instructions. When the computer program/instructions are executed by a processor, the control method provided by the second aspect, the fourth aspect, the fifth aspect, the seventh aspect, or the ninth aspect of the disclosure is implemented.

Related technical solutions are the same as the control methods provided by the second aspect, the fourth aspect, the fifth aspect, the seventh aspect, and the ninth aspect of the disclosure, and are not be repeated here.

Those skilled in the art can easily understand that the aforementioned descriptions are only preferred embodiments of the disclosure and are not intended to limit the disclosure. Any modifications, equivalent substitutions, and improvements made within the spirit and principles of the disclosure should be included within the protection scope of the disclosure.

What is claimed is:

1. A memristor-based majority circuit, configured to perform a majority operation on logic values a, b, c, comprising: a resistor and two identical memristors M₁, M₂, wherein a negative electrode of the memristor M₁ and a negative electrode of the memristor M₂ are both connected to a terminal of the resistor;
before performing, by the majority circuit, the majority operation on the logic values a, b, c, a resistance state of the memristor M₂ being a high resistance value state;
when performing, by the majority circuit, the majority operation on the logic values a, b, c, a resistance state of the memristor M₁ being a resistance state corresponding to the logic value c, a positive electrode of memristor M₁ being configured to connect a voltage −V(b)−Vₚ, a positive electrode of the memristor M₂ being configured to connect a voltage V(a), another terminal of the resistor being configured to connect a voltage −V(b), and a final resistance state of the memristor M₂ being a majority operation result of the logic values a, b, c;
wherein a high resistance state of a memristor corresponds to a logic value “0”, a low resistance state corresponds to a logic value “1”; and when b is 1, V(b) is Vₚ, when b is 0, V(b) is a voltage with an amplitude of 0, when a is 1, V(a) is Vₚ, when a is 0, V(a) is a voltage with an amplitude of 0, a voltage Vₚ satisfies: Vₛₑₜ/2<Vₚ<Vₛₑₜ, and Vₚ<2|Vᵣₑₛₑₜ|/3; Vₛₑₜ is a threshold for the memristor to transform from the high resistance state to the low resistance state, Vᵣₑₛₑₜ is a threshold for the memristor to transform from the low resistance state to the high resistance state, a resistance value of the resistor indicates R=\sqrt{R_{H}·R_{L}}; R_{H} and R_{L} are a high resistance state value and a low resistance state value of the memristor respectively.

2. A control method of a majority circuit, wherein the majority circuit is the majority circuit according to claim 1, the control method comprises:
when performing the majority operation on the logic values a, b, c, setting the resistance state of the memristor M₁ in the majority circuit to the resistance state corresponding to the logic value c, connecting the voltage −V(b)−Vₚ to the positive electrode of the memristor M₁, connecting the voltage V(a) to the positive electrode of the memristor M₂ in the majority circuit, connecting the voltage −V(b) to a terminal of the resistor in the majority circuit not connected to the memristor, and using the final resistance state of the memristor M₂ as the majority operation result of the logic values a, b, c;
wherein before the majority operation is performed on the logic values a, b, c, the resistance state of the memristor M₂ is the high resistance value state.

3. A majority operation device, comprising: a controller and the majority circuit according to claim 1;
the controller being configured to execute the control method according to claim 2.

4. A control method of an addition circuit, the addition circuit comprising: a resistor and four identical memristors M1, M2, M3, M4, wherein negative electrodes of the four memristors are all connected to a terminal of the resistor, a resistance value of the resistor indicates R=\sqrt{R_{H}·R_{L}}; R_{H} and R_{L} are a high resistance state value and a low resistance state value of the memristor respectively;
the control method comprises performing an addition operation on the addition circuit to implement a 1-bit addition of addends a, b and a carry input c:
S1: setting the memristor M₁ to a resistance state corresponding to c, resistance states of the memristors M₂, M₃, M₄ being high resistance value states at this time;
S2: making a positive electrode of the memristor M₃ and a positive electrode of the memristor M₄ in floating states, connecting a voltage −V(b)−Vₚ to a positive electrode of the memristor M₁, connecting a voltage V(a) to a positive electrode of the memristor M₂, connecting a voltage −V(b) to a terminal of the resistor not connected to the memristors, thereby obtaining a majority operation result of a, b, c corresponding to the resistance state of the memristor M₂, and acting as a carry result of the addition operation;
making the positive electrode of the memristor M₂, and the positive electrode of the memristor M₄ in floating states, connecting a voltage V(a)−2Vₚ to the positive electrode of the memristor M₁, connecting a voltage with an amplitude of 0 to the positive electrode of the memristor M₃, connecting a voltage −V(a)−Vₚ to a terminal of the resistor not connected to the memristors, thereby obtaining an XOR operation result of a, c corresponding to the resistance state of the memristor M₃; and
after obtaining the XOR operation result of a, c, making the positive electrode of the memristor M₁ and the positive electrode of the memristor M₂ in floating states, connecting a voltage V(b)−2Vₚ to the positive electrode of the memristor M₃, connecting a voltage with an amplitude of 0 to the positive electrode of the memristor M₄, connecting a voltage −V(b)−Vₚ to the terminal of the resistor not connected to the memristors, thereby obtaining an XOR operation result of a, b, c corresponding to the resistance state of the memristor M₄, and acting as a sum result of the addition operation;
wherein a high resistance state of a memristor corresponds to a logic value “0”, a low resistance state corresponds to a logic value “1”; when b is 1, V(b) is Vₚ; when b is 0, V(b) is a voltage with an amplitude of 0; when a is 1, V(a) is Vₚ; when a is 0, V(a) is a voltage with an amplitude of 0; a voltage Vₚ satisfies: Vₛₑₜ/2<Vₚ<Vₛₑₜ, and Vₚ<2|Vᵣₑₛₑₜ|/3; Vₛₑₜ is a threshold for the memristor to transform from the high resistance state to the low resistance state; Vᵣₑₛₑₜ is a threshold for the memristor to transform from the low resistance state to the high resistance state.

5. A control method of an addition circuit, configured to implement an addition operation of n-bit numbers aₙ, . . . , a₂a₁, bₙ, . . . , b₂b₁ and a 1-bit carry input c₁; wherein n≥2, the addition circuit comprises a resistor and four identical memristors M1, M2, M3, M4, negative electrodes of the four memristors are all connected to a terminal of the resistor; a resistance value of the resistor indicates R=\sqrt{R_{H}·R_{L}}; R_{H} and R_{L} are a high resistance state value and a low resistance state value of the memristor respectively;
the control method comprises: sequentially executing n rounds of an addition subprocesses; wherein in an i-th round of the addition subprocess, taking aᵢ as a, bᵢ as b, cᵢ as c, and executing the control method according to claim 4 on the addition circuit to obtain a carry result cₙ₊₁ and a sum result sᵢ of an i-th round of the addition operation; i=1, 2, . . . , n.

6. An addition operation device, comprising: an addition circuit and a controller;
the addition circuit comprising: a resistor and four identical memristors M1, M2, M3, M4; wherein negative electrodes of the four memristors are connected to a terminal of the resistor, a resistance value of the resistor indicates R=\sqrt{R_{H}·R_{L}}; R_{H} and R_{L} are a high resistance state value and a low resistance state value of the memristor respectively;
the controller is configured to execute the control method according to claim 4.

7. A control method of an addition circuit, configured to implement an addition operation of n-bit numbers aₙ, . . . , a₂a₁, bₙ, . . . , b₂b₁, and a 1-bit carry input c₁; wherein n≥2, the addition circuit comprises: a resistor and 2n+2 identical memristors, negative electrodes of the 2n+2 memristors are connected to a terminal of the resistor, a resistance value of the resistor indicates is R=\sqrt{R_{H}·R_{L}}; R_{H} and R_{L} are a high resistance state value and a low resistance state value of the memristor respectively;
the control method comprises: selecting one memristor from the 2n+2 memristors as a memristor M₃, and sequentially executing n rounds of an addition subprocesses;
wherein in an i-th round of the addition subprocess, i=1, 2, . . . , n:
when i=1, selecting one memristor from the remaining unselected memristors as a memristor M₁ in a current round of the addition subprocess, and setting the memristor to a resistance state corresponding to c₁; when i≥2, using a memristor M₂ from a previous round of the addition subprocess as the memristor M₁ in the current round of the addition subprocess;
selecting two memristors from the remaining unselected memristors as M₂, M₄ in the current round of the addition subprocess respectively; constituting the sub-addition circuit in the current round by the memristor M₃ and the memristors M₁, M₂, M₄ in the current round of the addition subprocess; wherein the memristor M₃ and the memristors M₂, M₄ in the current round of the addition subprocess are in the high resistance value states;
taking aᵢ as a, bᵢ as b, cᵢ as c, and executing S2 in the control method according to claim 4 on the sub-addition circuit in the current round, to obtain a carry result cᵢ₊₁ and a sum result sᵢ of an i-th round addition operation;
in each round of the addition subprocess, positive electrodes of remaining memristors except the memristor M₃ and the memristors M₁, M₂, M₄ in the current round of the addition subprocess are in floating states; and
after n rounds of the addition subprocesses, sₙ, . . . , s₂s₁, and cₙ₊₁ are results of the required addition operation.

8. An addition operation device, comprising: an addition circuit and a controller; the addition circuit comprising a resistor and 2n+2 identical memristors, wherein negative electrodes of the 2n+2 memristors are connected to a terminal of the resistor, a resistance value of the resistor indicates R=\sqrt{R_{H}·R_{L}}; R_{H} and R_{L} are a high resistance state value and a low resistance state value of the memristor respectively; n≥2;
the controller is configured to execute the control method according to claim 7.

9. A control method of an addition circuit, configured to implement an addition operation of n-bit numbers aₙ, . . . , a₂a₁, bₙ, . . . , b₂b₁, and a 1-bit carry input c₁; wherein n≥2, the addition circuit comprises n parallel branches and switch modules m₁, m₂, . . . , mₙ₋₁ configured to control connection or disconnection between adjacent two branches, an i-th switch module mᵢ is configured to control connection or disconnection between an i-th branch and a (i+1)-th branch, i=1, 2, . . . , n−1; the i-th branch comprises an i-th resistor Ri and three memristors whose negative electrodes are connected to a terminal of a resistor Ri; a n-th branch comprises a n-th resistor Rn and four memristors whose negative electrodes are connected to a terminal of a resistor Rn; all memristors of the addition circuit are identical, all resistors are identical, and a resistance value indicates is R=\sqrt{R_{H}·R_{L}}; R_{H} and R_{L} are a high resistance state value and a low resistance state value of the memristor respectively;
wherein the control method comprises:
S1: sequentially executing n−1 rounds of a carry calculation subprocesses; in an i-th round of the carry calculation subprocess, controlling the i-th switch module mᵢ to conduct to connect the i-th branch with the (i+1)-th branch, and disconnecting other switch modules;
when i=1, selecting one memristor from the i-th branch as a memristor M₁ in the i-th round of the carry calculation subprocess, and setting the memristor to a resistance state corresponding to c₁; when i≥2, using a memristor M₂ from a previous round of the carry calculation subprocess as the memristor M₁ in a current round of the carry calculation subprocess;
selecting one memristor from the (i+1)-th branch as a memristor M₂ in the i-th round of the carry calculation subprocess, a resistance state of the memristor M₂ being a high resistance value state at this time, and making positive electrodes of other memristors except the memristors M₁, M₂ in the current round of the carry calculation subprocess be in floating states;
connecting a voltage −V(bᵢ)−Vₚ to a positive electrode of the memristor M₁ in the current round of the carry calculation subprocess, connecting a voltage V(aᵢ) to a positive electrode of the memristor M₂ in the current round of the carry calculation subprocess, connecting a voltage −V(bᵢ) to a terminal of a resistor Rᵢ or a resistor Rᵢ₊₁ not connected to the memristors, thereby obtaining a majority operation result of aᵢ, bᵢ, cᵢ corresponding to the resistance state of the memristor M₂ in the current round of the carry calculation subprocess, and using the majority operation result of aᵢ, bᵢ, cᵢ as a carry result of the i-th round of the addition operation;
S2: disconnecting all switch modules, so that all branches are not connected; executing the n-th round of the carry calculation subprocess, and executing n rounds of sum calculation subprocesses in parallel;
wherein executing the n-th round of the carry calculation subprocess comprises:
using the memristor M₂ from the previous round of the carry calculation subprocess as the memristor M₁ in the current round of the carry calculation subprocess, selecting one unselected memristor from the n-th branch as the memristor M₂ in the n-th round of the carry calculation subprocess, the resistance state of the memristor M₂ being the high resistance value state at this time; and making the positive electrodes of other memristors in the n-th branch except the memristors M₁, M₂ in the current round of the carry calculation subprocess be in floating states;
connecting a voltage −V(bₙ)−Vₚ to the positive electrode of the memristor M₁ in the current round of the carry calculation subprocess, connecting a voltage V(aₙ) to the positive electrode of the memristor M₂ in the current round of the carry calculation subprocess, connecting a voltage −V(bₙ) to a terminal of the resistor Rₙ not connected to the memristors, thereby obtaining a majority operation result of aₙ, bₙ, cₙ corresponding to the resistance state of the memristor M₂ in the current round of the carry calculation subprocess, and using the majority operation result as a carry result of the n-th round of the addition operation;
executing n rounds of sum calculation subprocesses in parallel comprises:
for a j-th branch, using the memristor selected as the memristor M₁ in a j-th round of the carry calculation subprocess as a memristor Mⱼ₁; and selecting two unselected memristors from the j-th branch as memristors Mⱼ₃ and Mⱼ₄, and j=1, 2, . . . , n;
making a positive electrode of each memristor Mⱼ₄ be in a floating state, connecting a corresponding voltage V(aⱼ)−2Vₚ to a positive electrode of each memristor Mⱼᵢ in parallel, connecting a voltage with an amplitude of 0 to a positive electrode of each memristor Mⱼ₃ in parallel, connecting a corresponding voltage −V(aⱼ)−Vₚ to a terminal of each resistor Rⱼ not connected to the memristors in parallel, thereby obtaining an XOR operation result of aⱼ and cⱼ corresponding to a resistance state of each memristor Mⱼ₃ in parallel; and
making the positive electrode of each memristor Mⱼᵢ be in a floating state, after obtaining the XOR operation result of aⱼ and cⱼ, connecting a corresponding voltage V(bⱼ)−2Vₚ to the positive electrode of each memristor Mⱼ₃ in parallel, connecting a voltage with an amplitude of 0 to the positive electrode of each memristor Mⱼ₄ in parallel, connecting a corresponding voltage −V(bⱼ)−Vₚ to the terminal of each resistor Rⱼ not connected to the memristors in parallel, thereby obtaining an XOR operation result of aⱼ, bⱼ, and cⱼ corresponding to a resistance state of each memristor Mⱼ₄ in parallel, and using the XOR operation result of aⱼ, bⱼ, and cⱼ as a sum result of the addition operation;
wherein a high resistance state of a memristor corresponds to a logic value “0”, a low resistance state corresponds to a logic value “1”; when bⱼ is 1, V(bⱼ) is Vₚ; when bⱼ is 0, V(bⱼ) is a voltage with an amplitude of 0; when aⱼ is 1, V(aⱼ) is Vₚ; when aⱼ is 0, V(aⱼ) is a voltage with an amplitude of 0; a voltage Vₚ satisfies: Vₛₑₜ/2<Vₚ<Vₛₑₜ, and Vₚ<2|Vᵣₑₛₑₜ|/3; Vₛₑₜ is a threshold for the memristor to transform from the high resistance state to the low resistance state, and Vᵣₑₛₑₜ is a threshold for the memristor to transform from the low resistance state to the high resistance state.

10. An addition operation device, comprising: an addition circuit and a controller; wherein the addition circuit comprises n parallel branches and switch modules m₁, m₂, . . . , mₙ₋₁ configured to control connection or disconnection between adjacent two branches; n≥2; an i-th switch module mᵢ is configured to control connection or disconnection between an i-th branch and an (i+1)-th branch, i=1, 2, . . . , n−1, the i-th branch comprises an i-th resistor Rᵢ and three memristors whose negative electrodes are connected to a terminal of a resistor Rᵢ, the n-th branch comprises an n-th resistor Rn and four memristors whose negative electrodes are connected to a terminal of a resistor Rn, all memristors of the addition circuit are identical, all resistors are identical, and a resistance value indicates is R=\sqrt{R_{H}·R_{L}}; R_{H} and R_{L} are a high resistance state value and a low resistance state value of the memristor respectively;
the controller is configured to execute the control method according to claim 9.
